(19) United States
(12) Patent Application Publication
(10) Pub. No.: US 2022/0355417 A1
(43) Pub. Date: Nov. 10, 2022

(54) APPARATUS FOR MANUFACTURING DISPLAY DEVICE AND METHOD FOR MANUFACTURING DISPLAY DEVICE

(71) Applicant: Samsung Display Co., LTD., Yongin-si (KR)

(72) Inventors: Hyun Ung LEE, Seoul (KR); Je Yun RYU, Hwaseong-si (KR); Jin Soo KIM, Hwaseong-si (KR)

(21) Appl. No.: 17/736,023

(22) Filed: May 3, 2022

(30) Foreign Application Priority Data
May 4, 2021 (KR) 10-2021-0057824

(51) Int. Cl. B23K 26/362

(52) U.S. Cl. CPC B23K 26/362; H01L 27/3246

(57) ABSTRACT

An apparatus for manufacturing a display device and a method for manufacturing a display device are provided. The apparatus includes a stage; a laser module disposed above the stage and configured to output a laser beam; a scanner configured to receive the laser beam output from the laser module and irradiate the laser beam onto the stage; and a controller configured to control the laser module to irradiate the laser beam to a processing position while moving both the scanner and the stage in a first direction according to the processing position and a shape of a processing pattern.

### CROSS-REFERENCE TO RELATED APPLICATION

This application claims priority from and the benefit of Korean Patent Application No. 10-2021-0057824, filed on May 4, 2021, which is hereby incorporated by reference for all purposes as if fully set forth herein.

### BACKGROUND

### Field

Embodiments of the invention relate generally to an apparatus for manufacturing a display device and, more specifically, to a method for manufacturing a display device.

### Discussion of the Background

The importance of display devices has steadily increased with the development of multimedia technology. In response thereto, various types of display devices such as an organic light emitting display (OLED), a liquid crystal display (LCD) and the like have been used. Such display devices have been variously applied to various mobile electronic devices, for example, portable electronic devices such as a smart phone, a smart watch, and a tablet PC.

Recently, components for implementing various functions other than screen display tend to be mounted on the display device. A smartphone equipped with optical elements such as a camera, an infrared sensor, and the like is an example of such components.

The above information disclosed in this Background section is only for understanding of the background of the inventive concepts, and, therefore, it may contain information that does not constitute prior art.

### SUMMARY

Devices constructed and methods performed according to illustrative implementations of the invention are capable of providing an improved manufacturing process for a display device by performing a more rapid laser processing process by moving both a scanner and a stage during at least one step of the manufacturing process.

Devices constructed and methods performed according to illustrative implementations of the invention are capable of providing an improved manufacturing process for a display device by forming uniform spot intervals of a laser beam onto the display device when forming an optical hole for an optical element of the display device.

The display device may include an optical hole in order for an optical element to receive light. The optical hole of the display device may be formed through a laser processing process using a laser.

Aspects of the present disclosure provide an apparatus for manufacturing a display device and a method for manufacturing a display device, capable of performing a rapid laser processing process in order to form an optical hole in the display device.

Additional features of the inventive concepts will be set forth in the description which follows, and in part will be apparent from the description, or may be learned by practice of the inventive concepts.

An embodiment of an apparatus for manufacturing a display device includes a stage; a laser module disposed above the stage and configured to output a laser beam; a scanner configured to receive the laser beam output from the laser module and irradiate the laser beam onto the stage; and a controller configured to control the laser module to irradiate the laser beam to a processing position while moving both the scanner and the stage in a first direction according to the processing position and a shape of a processing pattern.

An embodiment of a method for manufacturing a display device includes moving a stage in a first direction; and irradiating a laser beam to a processing position while moving both a scanner and the stage in the first direction when the scanner is disposed in the processing position to form a processing pattern, wherein said irradiating a laser beam to a processing position while moving both a scanner and the stage in the first direction when the scanner is disposed in the processing position to form a processing pattern comprises: outputting, by a laser module irradiating the laser beam, a first pulse signal including a plurality of first pulses; and when a moving distance of the scanner is equal to an irradiation interval of the laser beam in the processing position, generating a second pulse signal including a second pulse synchronized with one of the plurality of first pulses to provide the second pulse signal to the laser module.

An embodiment of a method for manufacturing a display device includes moving is a stage in a first direction; and irradiating a laser beam to a processing position while moving both a scanner and the stage in the first direction when the scanner is disposed in the processing position to form a processing pattern, wherein said irradiating a laser beam to a processing position while moving both a scanner and the stage in the first direction when the scanner is disposed in the processing position to form a processing pattern comprises: outputting, by a laser module irradiating the laser beam, a first pulse signal including a plurality of first pulses; when a moving distance of the scanner is equal to an irradiation interval of the laser beam in the processing position, generating a second pulse signal including a second pulse synchronized with one of the plurality of first pulses; and generating a third pulse signal including a plurality of third pulses by using the second pulse signal and providing the third pulse signal to the laser module.

According to the apparatus for manufacturing a display device and the method for manufacturing a display device according to one embodiment, a rapid laser processing process may be performed by performing a laser processing process while moving both a scanner and a stage.

According to the apparatus for manufacturing a display device and the method for manufacturing a display device according to one embodiment, a precise laser processing process may be performed by forming uniform spot intervals of a laser beam.

However, the effects of the present disclosure are not limited to the aforementioned effects, and various other effects are included in the present specification.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a schematic diagram of an apparatus for manufacturing a display device according to one embodiment that is constructed according to principles of the invention.

FIG. 2 is an enlarged view of area Q of FIG. 1.

FIG. 3 is a schematic diagram illustrating a laser processing process using an apparatus for manufacturing a display device according to one embodiment.

FIG. 4 is a flowchart illustrating a method for manufacturing a display device according to one embodiment.

FIGS. 5 to 7 are schematic diagrams illustrating a method for manufacturing the display device of FIG. 4.

FIG. 8 is a schematic diagram illustrating a spot trace of a laser beam which appears when a display device manufacturing apparatus according to one embodiment irradiates a laser to a stationary object.

FIG. 9 is a flowchart illustrating step S3 of FIG. 4 according to one embodiment in detail.

FIGS. 10 to 12 are schematic diagrams illustrating step S3 of FIG. 4 according to one embodiment.

FIG. 13 is a flowchart illustrating step S3 of FIG. 4 according to another embodiment.

FIGS. 14 to 16 are schematic diagrams illustrating step S3 of FIG. 4 according to the embodiment of FIG. 13.

FIG. 17 is a flowchart showing a method for manufacturing a display device according to another embodiment.

FIG. 18 is a schematic diagram illustrating a display device manufacturing method according to the embodiment of FIG. 17.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

The present invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

Hereinafter, embodiments will be described in detail with reference to the accompanying drawings.

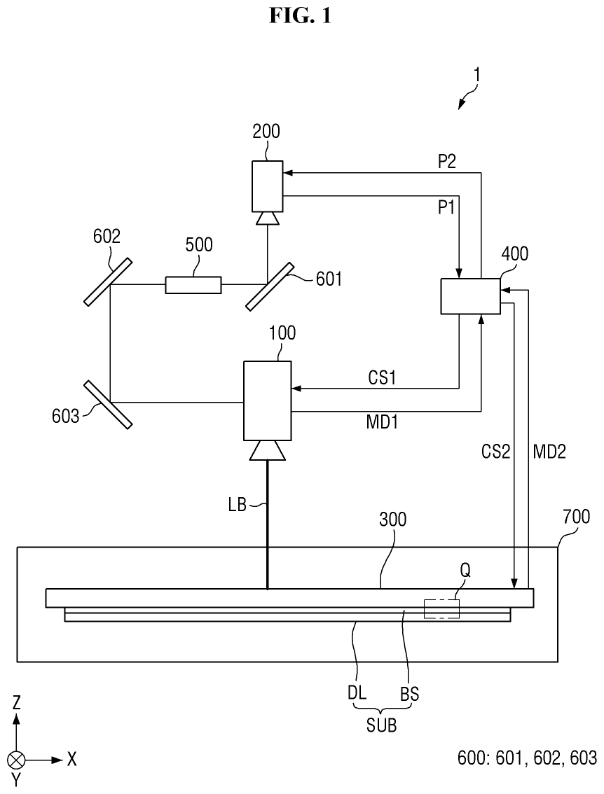

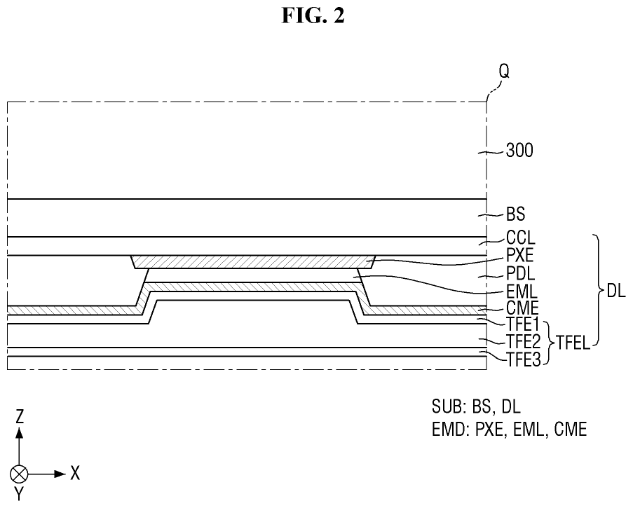

FIG. 1 is a schematic diagram of an apparatus for manufacturing a display device according to one embodiment that is constructed according to principles of the invention. FIG. 2 is an enlarged view of area Q of FIG. 1.

Referring to FIGS. 1 and 2, a display device manufacturing apparatus 1 according to one embodiment may include a scanner 100, a laser module 200, a stage 300, a controller 400, an optical system 500, a mirror 600, and a chamber 700.

The scanner 100 may receive a laser beam LB from the laser module 200 to irradiate the laser beam LB toward the stage 300. That is, light of the laser beam LB may pass through the scanner 100. Although not illustrated, the scanner 100 may include an optical member such as a lens, a mirror or the likes. The scanner 100 may move along a plane parallel to the top surface or the bottom surface of the stage 300 above the stage 300. The movement of the scanner 100 may be controlled by the controller 400.

The scanner 100 controls the output direction of the laser beam LB outputted from the laser module 200. That is, the scanner 100 controls a scanning field of the laser beam LB outputted from the laser module 200. Positions of the laser beam LB irradiated onto the stage 300 in a first direction X and in a second direction Y may be determined by the scanner 100. The scanner 100 may be a galvano scanner including a reflection mirror array having a plurality of reflection mirrors, but is not limited thereto.

In one embodiment, the first direction X and the second direction Y cross each other in directions different from each other. The first direction X may refer to an extension direction of one edge of the stage 300, and the second direction Y may refer to an extension direction of the other edge of the stage 300 crossing the one edge thereof. Also, a third direction Z may refer to a direction crossing both the first direction X and the second direction Y. It should be understood, however, that a direction mentioned in the embodiment refers to a relative direction and the embodiment is not limited to the direction mentioned. The scanner 100 may receive a first control signal CS1 from the controller 400. The controller 400 may control the location, the moving direction and the moving speed of the scanner 100 in response to the first control signal CS1. The scanner 100 may provide first movement data MD1 to the controller 400. The first movement data MD1 may include information such as the location, the moving direction and the moving speed of the scanner 100. The controller 400 may calculate the first control signal CS1 based on the first movement data MD1.

The laser module 200 may generate and emit the laser beam LB. The laser beam LB generated by the laser module 200 may be one of, e.g., CO2 laser, green laser, infrared laser, and ultraviolet laser, but is not limited thereto.

The laser module 200 may provide a first pulse signal P1 to the controller 400. The laser module 200 may receive a second pulse signal P2 which is synchronized with at least one of first pulses UP1 of the first pulse signal P1 from the controller 400. When inputting the second pulse signal P2, the laser module 200 may output the laser beam LB.

A target substrate SUB may be mounted and fixed on the stage 300. The laser beam LB irradiated onto the stage 300 may be irradiated onto the target substrate SUB and a part of the target substrate SUB may be removed.

In one embodiment, the stage 300 may include an electrostatic chuck. Through this configuration, the stage 300 may fix the target substrate SUB. For example, the target substrate SUB may be disposed and fixed on the bottom surface of the stage 300 which is the opposite surface of the top surface of the stage 300 facing the scanner 100. However, the embodiments described herein are not limited thereto, and the target substrate SUB may be disposed and fixed on the top surface of the stage 300 facing the scanner 100. In this case, the stage 300 may be made of a material capable of transmitting the laser beam LB, and the laser processing process may be carried out on the target substrate SUB by the laser beam LB transmitted through the stage 300 and irradiated onto the target substrate SUB.

The stage 300 may receive a second control signal CS2 from the controller 400. The controller 400 may control the location, the moving direction and the moving speed of the stage 300 in response to the second control signal CS2. The stage 300 may provide second movement data MD2 to the controller 400. The second movement data MD2 may include information such as the location, the moving direction and the moving speed of the stage 300. The controller 400 may calculate the second control signal CS2 based on the second movement data MD2.

Hereinafter, the target substrate SUB mounted on the stage 300 will be described. The target substrate SUB may include a base substrate BS and a deposition layer DL disposed on the base substrate BS. As shown in FIGS. 1 and 2, the deposition layer DL may be disposed below the base substrate BS.

The base substrate BS may be a transparent insulating substrate. The base substrate BS may be a rigid substrate such as glass, but is not limited thereto and may also be a flexible substrate.

The deposition layer DL may be disposed on the base substrate BS. The deposition layer DL may include a plurality of conductive layers and a plurality of insulating layers. The deposition layer DL may include a light emitting element EMD of the display device and a transistor driving the light emitting element EMD through a different process thereafter.

The deposition layer DL may include a circuit layer CCL, a pixel electrode PXE, a pixel defining layer PDL, a light emitting layer EML, a common electrode CME and a thin film encapsulation structure TFEL. The pixel electrode PXE, the light emitting layer EML, and the common electrode CME may constitute the light emitting element EMD.

The circuit layer CCL may be disposed on the base substrate BS. The pixel electrode PXE may be disposed on the circuit layer CCL. The circuit layer CCL may include a plurality of conductive layers for driving the light emitting element EMD. For example, the circuit layer CCL may include a semiconductor layer, a gate conductive layer, a data conductive layer and the like. The circuit layer CCL may further include an insulating layer disposed between each conductive layer.

The pixel defining layer PDL may be disposed along the edge of the pixel electrode PXE on the circuit layer CCL and may include an opening partially exposing the pixel electrode PXE. The light emitting layer EML may be disposed on the pixel electrode PXE exposed by the pixel defining layer PDL. The common electrode CME may be disposed entirely on the pixel defining layer PDL and the light emitting layer EML.

The thin film encapsulation structure TFEL may be disposed on the common electrode CME and may encapsulate the light emitting element EMD. The thin film encapsulation structure TFEL may include a first thin film encapsulation layer TFE1 disposed on the common electrode CME, a second thin film encapsulation layer TFE2 disposed on the first thin film encapsulation layer TFE1 and a third thin film encapsulation layer TFE3 disposed on the second thin film encapsulation layer TFE2. The first thin film encapsulation layer TFE1 and the third thin film encapsulation layer TFE3 may be made of an inorganic material, and the second thin film encapsulation layer TFE2 may be made of an organic material.

The deposition layer DL may be partially removed by the laser beam LB irradiated from the scanner 100. For example, at least one of the thin film encapsulation structure TFEL, the common electrode CME, the light emitting layer EML, the pixel defining layer PDL, the pixel electrode PXE, and the circuit layer CCL of the deposition layer DL may be removed. The deposition layer DL may be removed in a shape of a closed curve in plan view, or may be removed in a shape of a plurality of dots spaced apart from each other in a predetermined area.

The controller 400 may control the operations of the scanner 100, the laser module 200 and the stage 300. Specifically, the controller 400 may control the movement of the scanner 100 and the irradiation direction of the laser beam LB through the scanner 100. In addition, the controller 400 may control the laser beam LB generation of the laser module 200 and may control the movement of the stage 300.

The controller 400 may receive the first movement data MD1 from the scanner 100. The controller 400 may provide the first control signal CS1 to the scanner 100. The scanner 100 may move or control the optical path of the laser beam LB in response to the first control signal CS1. The controller 400 may generate the first control signal CS1 depending on whether the second movement data MD2 and the second pulse signal P2 are applied. That is, the controller 400 may generate the first control signal CS1 in consideration of the movement of the stage 300 and whether or not the laser beam LB is emitted by the laser module 200.

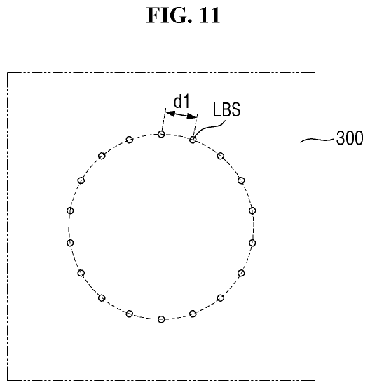

The controller 400 may control the irradiation of the laser beam LB by the scanner 100 in response to the first control signal CS1. In addition, the controller 400 may determine in real time whether the moving distance of the scanner 100 is the same as an irradiation interval d1 (see FIG. 11) of the laser beam LB based on the first movement data MD1. When the moving distance of the scanner 100 is the same as the irradiation interval d1 of the laser beam LB, the controller 400 may provide the second pulse signal P2 synchronized with the first pulse signal P1 to the laser module 200. The controller 400 may set an interval at which the second pulse signal P2 is provided in comprehensive consideration of the intensity and the type of the laser beam LB, the type of the substrate SB, and the likes.

The controller 400 may receive the first pulse signal P1 from the laser module 200. The first pulse signal P1 may include a plurality of first pulses UP1 having a predetermined period.

The controller 400 may generate the second pulse signal P2 according to the first movement data MD1 and the second movement data MD2 and provide the second pulse signal P2 to the laser module 200. The second pulse signal P2 may include a plurality of second pulses UP2. The second pulse UP2 may be synchronized with at least one of the first pulses UP1 of the first pulse signal P1. Specifically, when the scanner 100 has reached a position above a processing position PP inputted by a user through the movement of the stage 300, the controller 400 may provide the second pulse signal P2 to the laser module 200. Through this configuration, the laser module 200 may emit the laser beam LB based on the second pulse signal P2.

The controller 400 may receive the second movement data MD2 from the stage 300. The controller 400 may generate the second control signal CS2 depending on whether the first movement data MD1 and the second pulse signal P2 are applied and provide it to the stage 300. The controller 400 may control the movement of the stage 300 in response to the second control signal CS2.

In summary, the controller 400 may use the first movement data MD1 provided from the scanner 100, the second movement data MD2 provided from the stage 300, and the first pulse signal P1 provided from the laser module 200 to provide the first control signal CS1 to the scanner 100, provide the second control signal CS2 to the stage 300, and provide the second pulse signal P2 to the laser module 200.

The optical system 500 may be disposed between the laser module 200 and the scanner 100. The optical system 500 may include a plurality of lenses and mirrors. The optical system 500 may adjust the characteristics of the laser beam LB. For example, the optical system 500 may adjust a focus position of the laser beam LB, a size of a spot, and the intensity of energy, but the function or the role of the optical system 500 is not limited thereto.

The mirror 600 may be disposed between the laser module 200 and the scanner 100. The mirror 600 may reflect the laser beam LB to adjust the optical path between the laser module 200 and the scanner 100. The mirror 600 may be provided in plural number. The optical system 500 described above may be located between any two mirrors, which are adjacent to each other on the optical path, among the plurality of mirrors 600.

For example, the mirror 600 may include a first mirror unit 601 located between the laser module 200 and the optical system 500 on the optical path, and second and third mirror units 602 and 603 disposed between the optical system 500 and the scanner 100 on the optical path. As described above, the second and third mirror units 602 and 603 may be located between the optical system 500 and the scanner 100 on the optical path, but the second mirror unit 602 may be located between the third mirror unit 603 and the optical system 500 on the optical path, and the third mirror unit 603 may be located between the second mirror unit 602 and the scanner 100 on the optical path. The laser beam LB outputted from the laser module 200 may be reflected from the first mirror unit 601 to proceed to the optical system 500, and the laser beam LB having passed through the optical system 500 may be sequentially reflected from the second mirror unit 602 and the third mirror unit 603 to proceed to the scanner 100.

The chamber 700 may provide a space for accommodating the stage 300. That is, the stage 300 may be located inside the chamber 700. In one embodiment, the chamber 700 may be a vacuum chamber. While a laser processing process is performed, the inside of the chamber 700 may be maintained in a vacuum state.

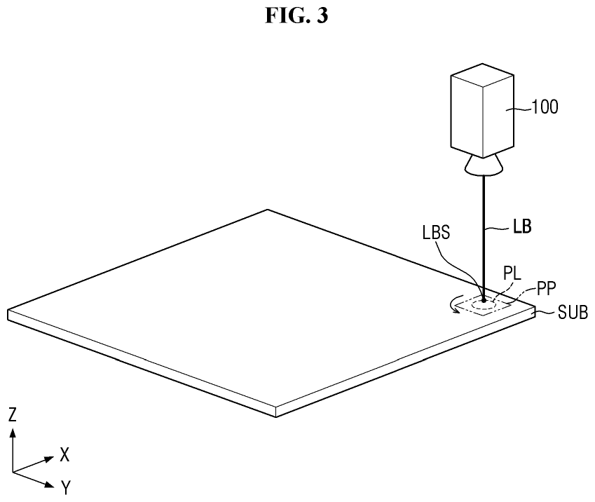

FIG. 3 is a schematic diagram illustrating a laser processing process using an apparatus for manufacturing a display device according to one embodiment.

In the following drawings including FIG. 3, only the scanner 100 and the target substrate SUB included in the display device manufacturing apparatus 1 are illustrated by simplifying the display device manufacturing apparatus 1 according to one embodiment. That is, only the scanner 100 is illustrated in the following drawings, but this means the display device manufacturing apparatus 1 according to one embodiment described above.

Referring to FIG. 3, the scanner 100 according to one embodiment may irradiate the laser beam LB onto the target substrate SUB. Specifically, the target substrate SUB may be disposed such that the top surface thereof is parallel to a plane defined by the first direction X and the second direction Y. The scanner 100 may be located above the target substrate SUB. For example, the scanner 100 may be located above the edge of the target substrate SUB. The scanner 100 may be located above a corner portion of the target substrate SUB. The scanner 100 may irradiate the laser beam LB toward the top surface of the target substrate SUB.

The scanner 100 according to one embodiment may irradiate the laser beam LB to the processing position PP formed on the target substrate SUB. When the laser beam LB is irradiated to the processing position PP formed on the target substrate SUB, a processing pattern PL may be formed. The laser beam LB may be irradiated to the target substrate SUB in the form of a plurality of beam spots LBS spaced apart from each other. The beam spot LBS may have predetermined coordinates in the first direction X and the second direction Y. The coordinates of the beam spot LBS in the first direction X and the second direction Y may be controlled by the controller 400.

In a case where the scanner 100 irradiates the laser beam LB onto the target substrate SUB, the focal point of the laser beam LB may be formed on the deposition layer DL of the target substrate SUB described above with reference to FIGS. 1 and 2. In short, when the laser beam LB is irradiated onto the target substrate SUB, the focal point of the laser beam LB may be formed inside the deposition layer DL. Accordingly, when the laser beam LB is irradiated onto the target substrate SUB, a part of the deposition layer DL may be removed. For example, when the laser beam LB is irradiated onto the target substrate SUB, at least one of the thin film encapsulation structure TFEL, the common electrode CME, the light emitting layer EML, the pixel defining layer PDL, the pixel electrode PXE and the circuit layer CCL of the deposition layer DL may be removed.

When the beam spots LBS of the laser beam LB irradiated onto the target substrate SUB are connected, a closed curve shape in plan view may be formed. Through this configuration, the processing pattern PL formed on the target substrate SUB may have a closed curve shape in plan view. For example, the processing pattern PL may have a circular shape, a triangular shape, a quadrilateral shape or other polygonal shapes in plan view. However, the embodiments described herein are not limited thereto, and the plurality of beam spots LBS may be arranged in a matrix so that the processing pattern PL may have a shape of a plurality of dots spaced apart from each other in a predetermined region.

In one embodiment, when a part of the deposition layer DL overlapping the processing pattern PL in a closed curve shape is removed, the region surrounded by the processing pattern PL in a closed curve shape in the deposition layer DL may be separated from the base substrate BS. That is, when the laser beam LB is irradiated onto the target substrate SUB, the region surrounded by the processing pattern PL in a closed curve shape may be removed. Various sensors or modules may be mounted in a region where the deposition layer DL is removed through laser processing. For example, a camera module may be mounted in the region where the deposition layer DL is removed through laser processing.

In another embodiment, in a case where the beam spots LBS of the laser beam LB are arranged in a matrix in a predetermined region on the target substrate SUB to have a shape of a plurality of dots spaced apart from each other, a pixel may not be disposed in the region where the processing pattern PL is formed. The region where the processing pattern PL is formed and thus no pixel is disposed may be a light transmission region that transmits light entering from the outside. Light coming from the outside may enter various sensors or modules disposed to overlap the light transmission region. In this case, for example, a fingerprint recognition sensor may be disposed to overlap the light transmission region, and the light coming from the outside may enter the fingerprint recognition sensor.

In summary, while the laser beam LB is irradiated onto the stage 300, the controller 400 continuously moves the scanner 100 and the stage 300, thereby performing rapid laser processing. In addition, the controller 400 irradiates the laser beam LB to a desired position at a desired timing based on information such as the second pulse signal P2 synchronized with the first pulse UP1 of the first pulse signal P1, the first and second movement data MD1 and MD2 and the processing position PP, thereby performing precise laser processing.

Hereinafter, a method for manufacturing a display device using the display device manufacturing apparatus 1 according to one embodiment, that is, a laser irradiation method, will be described.

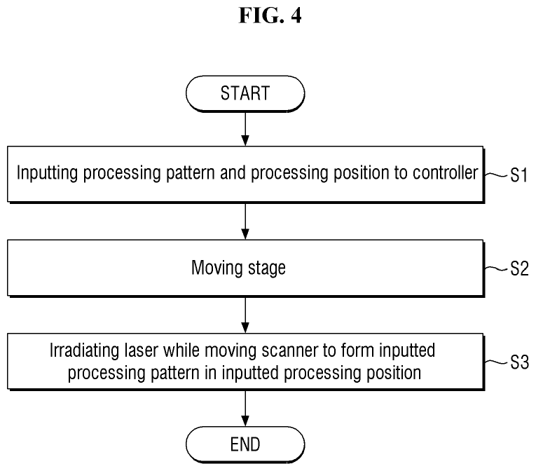

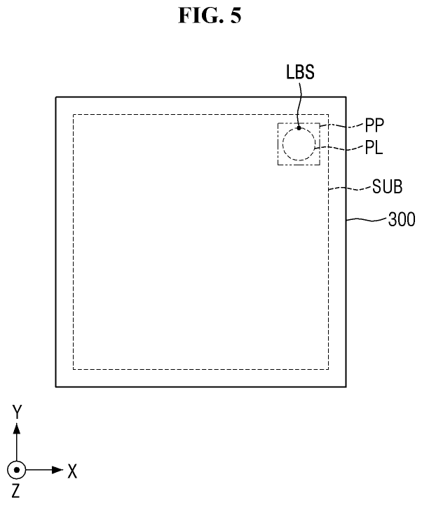

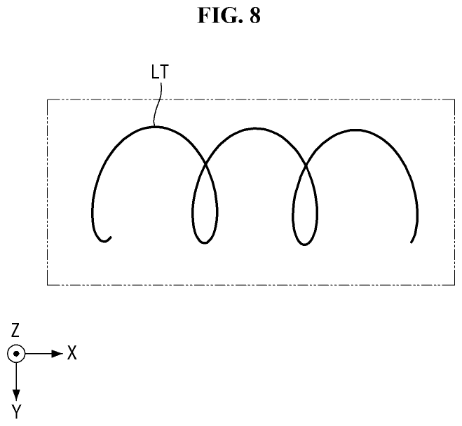

FIG. 4 is a flowchart illustrating a method for manufacturing a display device according to one embodiment. FIGS. 5 to 7 are schematic diagrams illustrating a method for manufacturing the display device of FIG. 4. FIG. 8 is a schematic diagram illustrating a spot trace of a laser beam which appears when a display device manufacturing apparatus according to one embodiment irradiates a laser to a stationary object.

First, as shown in FIG. 5, the processing pattern PL and the processing position PP may be inputted to the controller 400 (see FIG. 1) by the user (step S1).

That is, the user may input information about the processing pattern PL and the processing position PP to the controller 400 so that the display device manufacturing apparatus 1 according to one embodiment may use the laser beam LB to form the processing pattern PL and the processing position PP. The processing position PP indicates a position where the processing pattern PL is formed. That is, the processing pattern PL may be located in the processing position PP. The processing pattern PL may be formed by moving the beam spot LBS of the laser beam LB. FIG. 5 illustrates the processing position PP located in the corner portion of the target substrate SUB, but the embodiments described herein are not limited thereto.

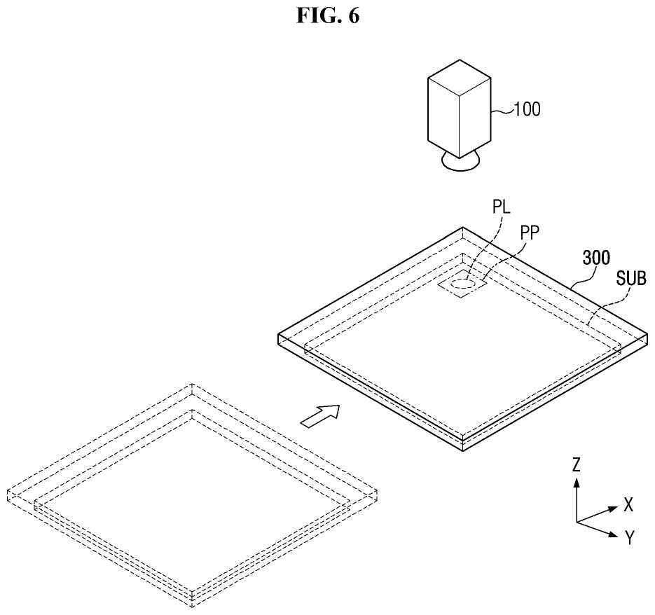

Second, as shown in FIG. 6, the stage 300 may be moved (step S2).

In the method for manufacturing a display device according to one embodiment, the stage 300 may move along the first direction X until substantial laser processing is carried out. That is, the stage 300 may move until the scanner 100 reaches a position above the inputted processing position PP.

In addition, the stage 300 may move continuously even when substantial laser processing is being carried out in the laser processing process using the method for manufacturing the display device according to one embodiment.

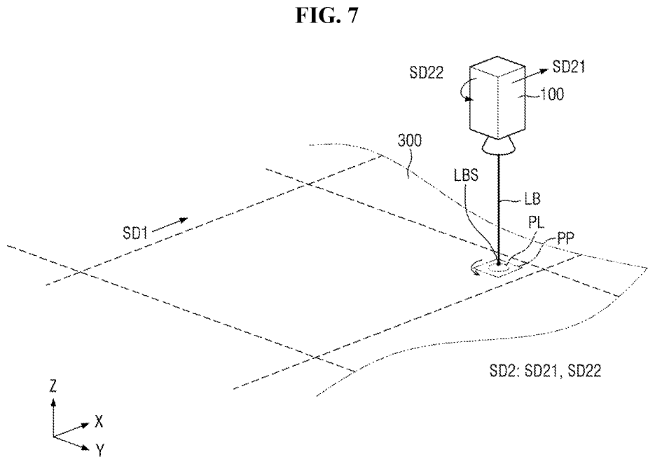

Third, as shown in FIG. 7, by irradiating a laser while moving both the stage 300 and the scanner 100, the inputted processing pattern PL may be formed in the inputted processing position PP (step S3).

The direction of movement SD1 of the stage 300 is illustrated as the first direction X in FIG. 7, but the embodiments described herein are not limited thereto. The direction of the movement SD1 of the stage 300 may be the second direction Y or a direction between the first direction X and the second direction Y.

When the scanner 100 is located on one side of the third direction Z of (i.e., above) the processing position PP of the stage 300, the scanner 100 may irradiate the laser beam LB toward the processing position PP of the stage 300. Although FIG. 7 illustrates only the stage 300, the target substrate SUB may be mounted and fixed on the bottom surface of the stage 300, which is a surface on the other side of the third direction Z.

As described above, even when the laser beam LB is being irradiated in real time, the stage 300 may move SD1 along the first direction X. In this case, the moving speed of the stage 300 in the first direction X may be substantially the same as the moving speed of the scanner 100 in the first direction X. Accordingly, the scanner 100 may move in order to form the desired processing pattern PL and irradiate the laser beam LB onto the stage 300. Movement SD2 of the scanner 100 when irradiating the laser beam LB may include first movement SD21 which is translational movement in one direction and second movement SD22 of moving in the same shape as the processing pattern PL.

The first movement SD21 of the scanner 100 may be intended to match the movement SD1 of the stage 300 which is performed while irradiating the laser beam LB. Since the stage 300 moves (‘SD1’) in real time when the scanner 100 irradiates the laser beam LB, the scanner 100 may involve the first movement SD21 of moving in the same direction and at the same speed as the movement SD1 of the stage 300 in order to form the desired processing pattern.

The second movement SD22 of the scanner 100 may be intended to form the processing pattern PL on the stage 300. That is, the scanner 100 may move in the same shape as the processing pattern through the second movement SD22. For example, when the processing pattern PL formed on the stage 300 is a closed curve, the scanner 100 may move, as the second movement SD22, while drawing a closed curve above the processing pattern PL in the same shape as the processing pattern PL. The second movement SD22 of the scanner 100 may be performed multiple times in order to form a single processing pattern PL. That is, the scanner 100 may perform the first movement SD21 and the second movement SD22 at the same time while irradiating the laser beam LB.

FIG. 8 illustrates a spot trace LT in plan view formed by irradiating the laser beam LB while the scanner 100 performs both the first movement SD21 and the second movement SD22 when the stage 300 is in a fixed state without moving. The spot trace LT formed on the stage 300 may be a trace of the beam spot LBS of the laser beam LB.

The spot trace LT of the laser beam LB in plan view may be formed by simultaneously performing the first movement SD21 which is translation movement of the scanner 100 in the first direction X and the second movement SD22 which is circular movement to form the processing pattern PL while the laser beam LB is irradiated. Accordingly, the planar shape of the spot trace LT may be, for example, a swirl, spiral or helical shape.

FIG. 8 illustrates the spot trace LT of the laser beam LB as the result of performing the first movement SD21 and repetitively performing the second movement SD22 three times, but the repetition number of the second movement SD22 is not limited thereto, and the shape of the spot trace LT of the laser beam LB may vary depending on the repetition number of the second movement SD22.

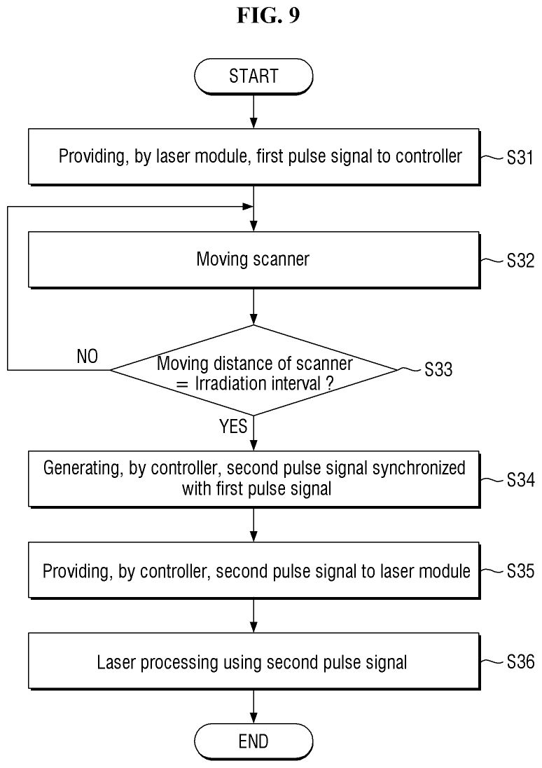

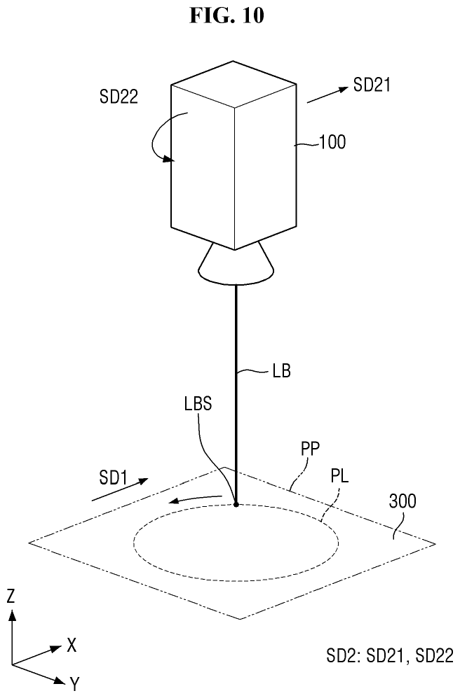

FIG. 9 is a flowchart illustrating step S3 of FIG. 4 according to one embodiment in detail. FIGS. 10 to 12 are schematic diagrams illustrating step S3 of FIG. 4 according to one embodiment.

A process of making one processing pattern PL during the laser beam LB irradiation process will be described later with reference to FIGS. 9 to 12. In the laser processing process, the laser beam LB may be periodically emitted and irradiated in response to the second pulse signal P2 provided to the laser module 200.

First, the laser module 200 may provide the first pulse signal P1 to the controller (step S31).

The first pulse signal P1 may include a plurality of first pulses UP1 that are repeatedly provided as synchronization pulses continuously provided by the laser module 200 toward the controller 400. When the controller 400 provides the second pulse signal P2 synchronized with the first pulse signal P1 to the laser module 200, the laser module 200 may generate the laser beam LB and emit the laser beam LB toward the scanner 100. That is, the second pulse signal P2 may be a pulse controlling the generation of the laser beam LB.

Second, as shown in FIG. 10, the scanner 100 may move thereafter (step S32).

Here, the movement SD2 of the scanner 100 may include the first movement SD21 which is the movement in the same direction as the movement SD1 of the stage 300 and the second movement SD22 which is the movement to form the processing pattern PL. In the movement SD2 of the scanner 100, the first movement SD21 may be translational movement. The second movement SD22 may be movement of moving along the planar shape of the processing pattern PL. For example, when the processing pattern PL is a circular shape in plan view, the second movement SD22 of the scanner 100 may be circular movement enabling the beam spot LBS of the laser beam LB to move along the processing pattern PL.

Third, as shown in FIG. 11, the controller 400 may determine whether an irradiation interval d1 and a moving distance of the scanner 100 are the same (step S33).

The determination of the controller 400 may take place in real time together with the movement SD2 of the scanner 100. The beam spot LBS of the laser beam LB may be irradiated at regular irradiation intervals d1. That is, the irradiation interval d1 may mean an interval between the beam spots LBS adjacent to each other among the beam spots LBS formed by the laser beam LB. For example, after irradiating the laser beam LB once to form one of the beam spots LBS, the scanner 100 may perform both the first movement SD21 and the second movement SD22 to move by the irradiation interval d1, and then the laser beam LB may be irradiated again to form another beam spot LBS.

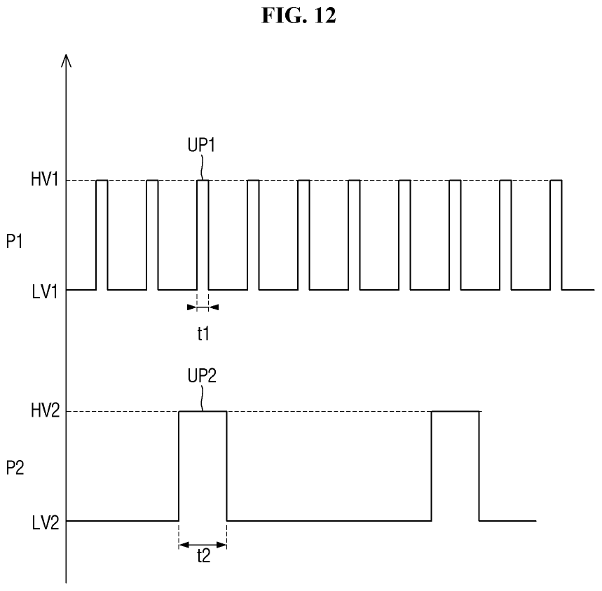

Fourth, as shown in FIG. 12, in a case where the irradiation interval d1 and the moving distance of the scanner 100 are the same when the controller 400 determines whether the irradiation interval d1 and the moving distance of the scanner 100 are the same, the controller 400 may generate the second pulse signal P2 synchronized with the first pulse signal P1 (step S34).

Fifth, the controller 400 may provide the second pulse signal P2 to the laser module 200 (step S35).

The second pulse signal P2 may include a plurality of second pulses UP2 controlling the emission of the laser beam LB. The second pulse UP2 of the second pulse signal P2 may be a pulse synchronized with the first pulse UP1 of the first pulse signal P1 which is a synchronization pulse provided from the laser module 200 to the controller 400. When the controller 400 provides the second pulse signal P2 toward the laser module 200, the laser module 200 may emit the laser beam LB. A time width t2 of the second pulse UP2 of the second pulse signal P2 may be greater than a time width t1 of the first pulse UP1 of the first pulse signal P1. The time width t1 of the first pulse UP1 of the first pulse signal P1 may be located within the time width t2 of the second pulse UP2 of the second pulse signal P2. However, the embodiments described herein are not limited thereto, and the time width t2 of the second pulse UP2 of the second pulse signal P2 may be smaller than the time width t1 of the first pulse UP1 of the first pulse signal P1. In this case, the time width t2 of the second pulse UP2 of the second pulse signal P2 may be located within the time width t1 of the first pulse UP1 of the first pulse signal P1.

In one embodiment, the laser module 200 may generate and emit the laser beam LB at a rising edge timing re of the second pulse UP2 of the second pulse signal P2. That is, the laser module 200 may generate and emit the laser beam LB at the timing re in which the second pulse UP2 starts. However, the embodiments described herein are not limited thereto, and the laser module 200 may generate and emit the laser beam LB at a falling edge timing fe of the second pulse UP2 of the second pulse signal P2. That is, the laser module 200 may generate and emit the laser beam LB at the timing fe in which the second pulse UP2 ends.

In one embodiment, the first pulse UP1 of the first pulse signal P1 may have a first high potential HV1 and a first low potential LV1. The second pulse UP2 of the second pulse signal P2 may have a second high potential HV2 and a second low potential LV2. The first low potential LV1 and the second low potential LV2 may be the same potential, but the embodiments described herein are is not limited thereto. The difference between the first high potential HV1 and the first low potential LV1 may be greater than the difference between the second high potential HV2 and the second low potential LV2, but the embodiments described herein are not limited thereto, and the difference between the first high potential HV1 and the first low potential LV1 may be smaller than the difference between the second high potential HV2 and the second low potential LV2.

Sixth, laser processing using the second pulse signal P2 may be performed (step S36). When the second pulse signal P2 is provided from the controller 400 to the laser module 200, the laser beam LB is provided from the laser module 200 toward the scanner 100, and the scanner 100 and the stage 300 may move simultaneously to perform laser processing for irradiating the laser beam LB.

When the irradiation interval d1 and the moving distance of the scanner 100 are not the same in step S33 of determining whether the moving distance of the scanner 100 and the irradiation interval are the same by the controller 400, the scanner 100 may move again (step S32).

In the method for manufacturing a display device according to one embodiment, rapid laser processing may be performed by irradiating the laser beam LB to the stage 300 while moving both the scanner 100 and the stage 300. In addition, in the method for manufacturing the display device according to one embodiment, precise laser processing for forming a desired processing pattern PL may be performed by controlling the second pulse signal P2 synchronized with the first pulse signal P1 provided from the laser module 200 to the controller 400 and irradiating the laser beam LB to the inputted processing position PP at a desired timing.

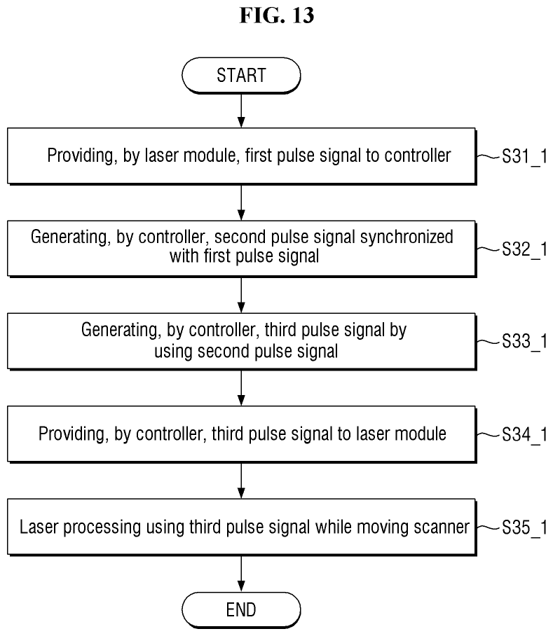

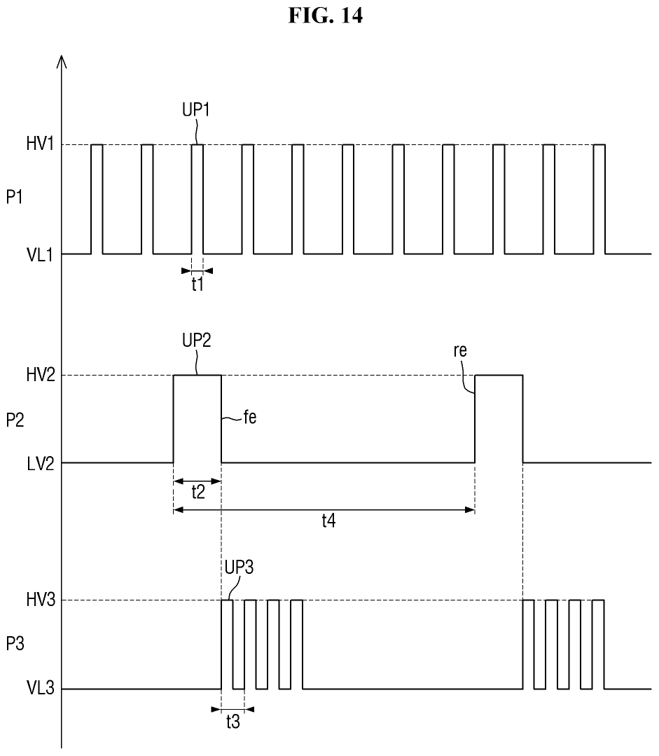

FIG. 13 is a flowchart illustrating step S3 of FIG. 4 according to another embodiment. FIGS. 14 to 16 are schematic diagrams illustrating step S3 of FIG. 4 according to another embodiment.

A method for manufacturing a display device to be described later with reference to FIGS. 13 to 16 has a difference from the embodiment of FIG. 9 in that a plurality of third pulse signals P3 are generated by using the second pulse signal P2, the generated plurality of third pulse signals P3 are provided to the laser module 200, and the laser module 200 is controlled to generate the laser beam LB.

First, as shown in FIG. 14, the laser module 200 may provide the first pulse signal P1 to the controller 400 (step S31_1).

Since step S31_1 is substantially the same as step S31 of FIG. 9, a description thereof will be omitted.

Second, the controller 400 may generate the second pulse signal P2 synchronized with the first pulse signal P1 (step S32_1).

The second pulse signal P2 may include second pulses UP2 synchronized with at least one of the first pulses UP1 of the first pulse signal P1 which is the synchronization pulse provided from the laser module 200 to the controller 400.

Third, as shown in FIG. 14, the controller 400 may generate the third pulse signal P3 by using the second pulse signal P2 (step S33_1).

One third pulse signal P3 may correspond to one second pulse UP2 of the second pulse signal P2. One third pulse signal P3 may include a plurality of third pulses UP3. For example, the third pulse signal P3 may include two, three, four or more third pulses UP3, but the number of the third pulses UP3 included in the third pulse signal P3 is not limited thereto. One of the plurality of third pulses UP3 may be synchronized with the second pulse UP2 of the second pulse signal P2.

As described above with reference to FIG. 12, the first pulse UP1 of the first pulse signal P1 may have the first high potential HV1 and the first low potential LV1, and the second pulse UP2 of the second pulse signal P2 may have the second high potential HV2 and the second low potential LV2. The third pulse UP3 of the third pulse signal P3 may have a third high potential HV3 and a third low potential LV3. The third low potential LV3 may be the same potential as the first low potential LV1 and the second low potential LV2, but the embodiments described herein are not limited thereto.

Each time interval t3 of the third pulse signals P3 may be constant.

The third pulse signal P3 may be generated in accordance with the falling edge timing fe of the second pulse UP2 of the second pulse signal P2. That is, the third pulse signal P3 may be generated in accordance with the timing fe at which the second pulse UP2 ends. However, the embodiments described herein are not limited thereto, and the third pulse signal P3 may be generated in accordance with the rising edge timing re of the second pulse UP2 of the second pulse signal P2. That is, the third pulse signal P3 may be generated in accordance with the timing re at which the second pulse UP2 starts.

Fourth, the controller 400 may provide the third pulse signal P3 to the laser module 200 (step S34_1).

The third pulse UP3 of the third pulse signal P3 may be a pulse that controls the laser module 200 to generate the laser beam LB. In the embodiment described herein, when the third pulse UP3 of the third pulse signal P3 is inputted to the laser module 200, the laser module 200 may generate and emit the laser beam LB. That is, the laser module 200 may be synchronized with the third pulse UP3 of the third pulse signal P3 to emit the laser beam LB. For example, when the third pulse UP3 of the third pulse signal P3 is generated once, the laser beam LB may be emitted once from the laser module 200. In addition, as illustrated in FIG. 14, when the third pulse signal P3 includes four third pulses UP3, the laser module 200 may emit the laser beam LB four times according to the third pulse signal P3.

In the embodiment described herein, the laser module 200 may generate and emit the laser beam LB at a rising edge timing of the third pulse UP3 of the third pulse signal P3. That is, the laser module 200 may generate and emit the laser beam LB at a timing when the third pulse UP3 starts. However, the embodiments described herein are not limited thereto, and the laser module 200 may generate and emit the laser beam LB at a falling edge timing of the third pulse UP3 of the third pulse signal P3. That is, the laser module 200 may generate and emit the laser beam LB at a timing when the third pulse UP3 ends.

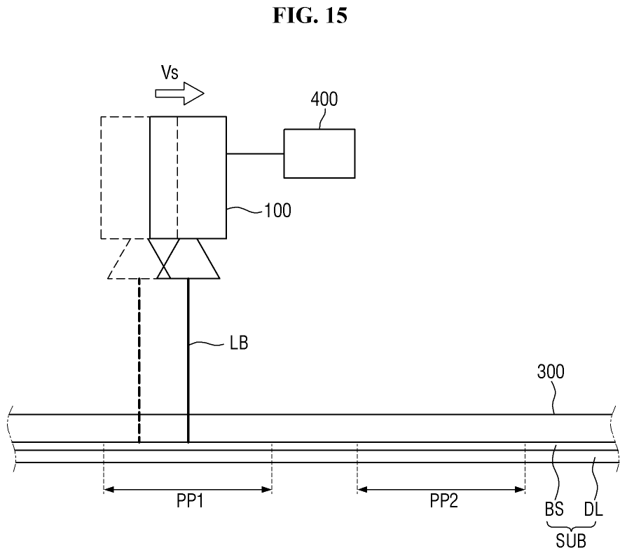

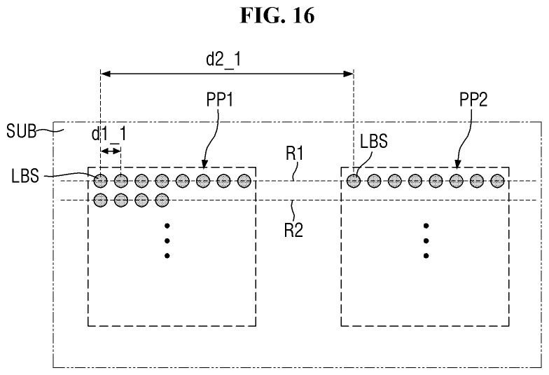

Fifth, as shown in FIGS. 15 and 16, the scanner 100 may move and use the third pulse signal P3 to perform laser processing (step S35_1).

In the present step, a moving speed Vs of the scanner 100 may be determined by an interval d1_1 between the beam spots LBS and the time interval t3 of the third pulse UP3 of the third pulse signal P3. That is, the time interval t3 of the third pulse UP3 of the third pulse signal P3 may be the same as the temporal irradiation interval of the laser beam LB.

In the embodiment described herein, the stage 300 may include a plurality of processing positions PP1 and PP2. For example, the stage 300 may include the first processing position PP1 and the second processing position PP2 disposed to be spaced apart from the first processing position PP 1.

The scanner 100 may irradiate the laser beam LB along a first row R1 in the first processing position PP1, and move to the second processing position PP2 to irradiate the laser beam LB along the first row R1 in the second processing position PP2. When the formation of the beam spot LBS is completed by irradiating the laser beam LB to the first row R1 in the first processing position PP1 and the second processing position PP2, the scanner 100 may move to a second row R2 of the first processing position PP1 and the second processing position PP2 to irradiate the laser beam LB and form the beam spot LBS. In the first processing position PP1, the laser beam LB may be irradiated multiple times to form the plurality of beam spots LBS. Also, in the second processing position PP2, the laser beam LB may be irradiated multiple times to form the plurality of beam spots LBS. The second pulse UP2 for generating a first group of laser beams LB irradiated in the first processing position PP1 and the second pulse UP2 for generating a second group of laser beams LB irradiated in the second processing position PP2 may be synchronized with the first pulses UP1 different from each other.

The interval d1_1 between the beam spots LBS of the laser beam LB formed by using the third pulse signal P3 including the plurality of third pulses UP3 may be constant. The interval d1_1 between the beam spots LBS may be expressed as a product of the moving speed Vs of the scanner 100 and the time interval t3 between the third pulses UP3 adjacent to each other among the plurality of third pulses UP3 of the third pulse signal P3. Accordingly, the interval d1_1 between the beam spots LBS may be controlled by adjusting the moving speed Vs of the scanner 100 and the time interval t3 between the third pulses UP3 adjacent to each other in the third pulse signal P3 through the controller 400.

An interval d2_1 between the first beam spot LBS of the first processing position PP1 and the first beam spot LBS of the second processing position PP2 may be controlled by adjusting a time interval t4 between the second pulses UP2. For example, the interval d2_1 between the first beam spot LBS of the first processing position PP1 and the first beam spot LBS of the second processing position PP2 may be expressed as a product of the moving speed of the scanner 100 and the time interval t4 between the second pulses UP2. That is, the time interval t4 between the second pulses UP2 may be substantially the same as an irradiation repetition period of the first group of laser beams LB and the second group of laser beams LB.

In the method for manufacturing a display device according to the embodiment described herein, the controller 400 may perform control to generate the second pulse signal P2 synchronized with the first pulse signal P1 provided from the laser module 200 and generate the third pulse signal P3 including the plurality of third pulses UP3 by using the second pulse signal P2 to perform the laser beam LB irradiation process. The method for manufacturing a display device according to the embodiment described herein may perform rapid laser processing by continuously moving the scanner 100 and the stage 300 while irradiating the laser beam LB to the stage 300. In addition, the laser beam LB is irradiated to a desired position at a desired timing based on information such as the second pulse signal P2 synchronized with the first pulse UP1 of the first pulse signal P1, the first and second movement data MD1 and MD2, and the processing position PP, thereby performing precise laser processing.

Moreover, in the method for manufacturing a display device according to the embodiment described herein, the controller 400 may generate the third pulse signal P3 including the plurality of third pulses UP3 using the second pulse signal P2 and provide the third pulse signal P3 having the time interval t3 of the uniform third pulses UP3 to the laser module 200 to generate the laser beam LB, thereby more precisely controlling the interval between the beam spots LBS.

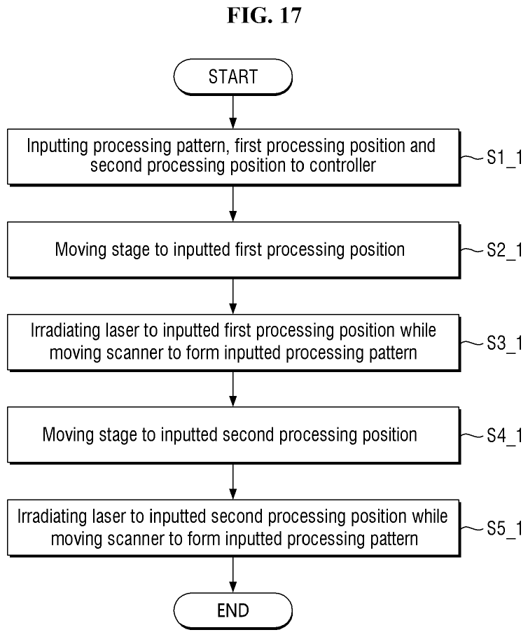

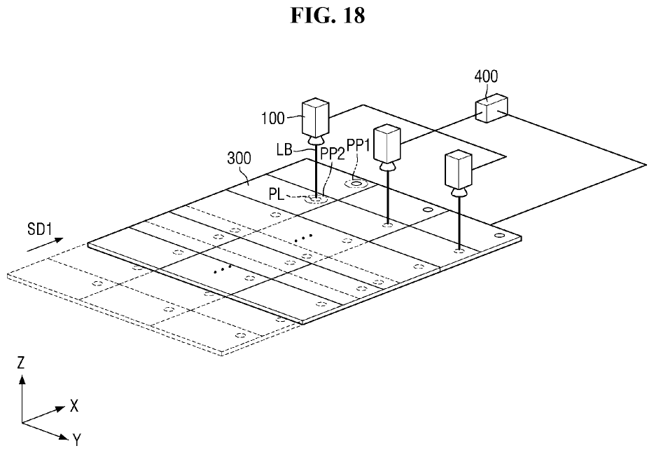

FIG. 17 is a flowchart showing a method for manufacturing a display device according to another embodiment. FIG. 18 is a schematic diagram illustrating a display device manufacturing method according to the embodiment of FIG. 17.

A method for manufacturing a display device according to another embodiment will be described with reference to FIGS. 17 and 18.

First, the processing pattern PL, the first processing position PP1 and the second processing position PP2 may be inputted to the controller 400 by the user (step S11).

That is, the user may input the processing pattern PL, the first processing position PP1 and the second processing position PP2 to the controller 400 such that the display device manufacturing apparatus 1 uses the laser beam LB to form a desired processing pattern PL in the first processing position PP1 and the second processing position PP2. Here, the processing pattern PL may mean an imaginary processing line to which the laser beam LB is irradiated. In addition, the first processing position PP1 and the second processing position PP2 may mean positions in which the processing pattern PL is formed. When the target substrate SUB is a parent substrate including a plurality of cells, the first processing position PP1 and the second processing position PP2 may be located at the edge of each cell included in the target substrate SUB. For example, the first processing position PP1 and the second processing position PP2 may be located at the corner portion of each cell included in the target substrate SUB.

Second, the stage 300 may move to the inputted first processing position PP1 (step S2_1).

In the method for manufacturing a display device according to the embodiment described herein, the stage 300 may move along the first direction X until substantial laser irradiation is carried out. That is, the stage 300 may move until the scanner 100 reaches a position above the inputted first processing position PP1.

The laser processing process using the method for manufacturing a display device according to the embodiment described herein may be carried out while the stage 300 is stopped.

Third, the scanner 100 may move and irradiate the laser beam LB to the inputted first processing position PP1 to form the inputted processing pattern PL (step S3_1).

In the present step, the laser beam LB may be irradiated while the stage 300 is stopped. When the scanner 100 is located above the first processing position PP1, the laser beam LB may be irradiated from the scanner 100 toward the stage 300 to form the processing pattern PL. In this case, various signals required for moving the stage 300 may not be applied from the controller 400 to the stage 300. Accordingly, noise caused by various signals which may be generated in the stage 300 may decrease, improving positional accuracy of the stage 300 with respect to the first processing position PP1.

Fourth, the stage 300 may move to the inputted second processing position PP2 (step S4_1).

In the method for manufacturing a display device according to the embodiment described herein, the stage 300 may move along the first direction X until the scanner 100 reaches a position above the inputted second processing position PP2.

Fifth, the scanner 100 may move and irradiate the laser beam LB to the inputted second processing position PP2 to form the inputted processing pattern PL (step S5_1).

In the present step, the laser beam LB may be irradiated while the stage 300 is stopped. When the scanner 100 moves to be located above the second processing position PP2, the laser beam LB may be irradiated from the scanner 100 toward the stage 300 to form the processing pattern PL. In this case, various signals required for moving the stage 300 may not be applied from the controller 400 to the stage 300. Accordingly, noise caused by various signals which may be generated in the stage 300 may decrease, improving positional accuracy of the stage 300 with respect to the second processing position PP2.

In the embodiment described herein, descriptions of step S3_1 of moving the scanner and irradiating a laser to the inputted first processing position to form the inputted processing pattern and step S5_1 of moving the scanner and irradiating a laser to the inputted second processing position to form the inputted processing pattern are substantially the same as the above descriptions with reference to FIGS. 9 to 12 or the above descriptions with reference to FIGS. 13 to 16 and therefore, redundant descriptions will be omitted.

The method for manufacturing a display device according to the embodiment described herein may generate the second pulse signal P2 synchronized with the first pulse signal P1 provided from the laser module 200 and generate the plurality of third pulse signals P3 by using the second pulse signal P2 to perform the laser beam LB irradiation process. The method for manufacturing a display device according to the embodiment described herein may perform precise laser processing through control using the second pulse signal P2 synchronized with the first pulse signal P1 provided from the laser module 200 to the controller 400.

In addition, the display device manufacturing apparatus 1 according to the embodiment described herein may maintain the stage 300 in a stopped state while irradiating the laser beam LB, thereby improving positional accuracy of the stage 300 with respect to the processing positions PP1 and PP2. Accordingly, more precise laser processing may be performed.

However, the effects of the embodiments are not restricted to the one set forth herein. The above and other effects of the embodiments will become more apparent to one of daily skill in the art to which the embodiments pertain by referencing the claims.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An apparatus for manufacturing a display device, comprising:
a stage;
a laser module disposed above the stage and configured to output a laser beam;
a scanner configured to receive the laser beam output from the laser module and irradiate the laser beam onto the stage; and
a controller configured to control the laser module to irradiate the laser beam to a processing position while moving both the scanner and the stage in a first direction according to the processing position and a shape of a processing pattern.

2. The apparatus of claim 1, wherein the scanner performs, in the processing position, both a first movement of moving in the first direction at a first speed and a second movement of moving in a same shape as the shape of the processing pattern.

3. The apparatus of claim 2, wherein the stage moves in the first direction at the first speed when the scanner is disposed in the processing position.

4. The apparatus of claim 1, wherein the processing position includes a first processing position disposed in the stage and a second processing position spaced apart from the first processing position in the first direction.

5. The apparatus of claim 4, wherein when the scanner is located between the first processing position and the second processing position, the controller is configured to move both the stage and the scanner at a first speed in the first direction.

6. The apparatus of claim 1, wherein when the controller is configured to stop movement of the stage in the first direction when the scanner is located in the processing position.

7. The apparatus of claim 6, wherein the scanner moves in a same shape as the shape of the processing pattern in the processing position.

8. The apparatus of claim 1, wherein the laser module provides a first pulse signal including a plurality of first pulses to the controller, and
the controller generates a second pulse signal including a second pulse synchronized with one of the plurality of first pulses, and outputs the second pulse signal to the laser module.

9. The apparatus of claim 8, wherein the laser module outputs the laser beam in synchronization with the second pulse of the second pulse signal.

10. The apparatus of claim 1, wherein the laser module provides a first pulse signal including a plurality of first pulses to the controller,
the controller generates a second pulse signal including a second pulse synchronized with one of the plurality of first pulses, and generates a third pulse signal including a plurality of third pulses by using the second pulse, and
the third pulse signal is outputted by the laser module.

11. The apparatus of claim 10, wherein the laser module outputs the laser beam in synchronization with the third pulse of the third pulse signal.

12. A method for manufacturing a display device, comprising:
moving a stage in a first direction; and
irradiating a laser beam to a processing position while moving both a scanner and the stage in the first direction when the scanner is disposed in the processing position to form a processing pattern,
wherein the irradiating a laser beam to a processing position while moving both a scanner and the stage in the first direction when the scanner is disposed in the processing position to form a processing pattern comprises:
outputting, by a laser module irradiating the laser beam, a first pulse signal including a plurality of first pulses; and
when a moving distance of the scanner is equal to an irradiation interval of the laser beam in the processing position, generating a second pulse signal including a second pulse synchronized with one of the plurality of first pulses to provide the second pulse signal to the laser module.

13. The method of claim 12, wherein the irradiating a laser beam to a processing position while moving both a scanner and the stage in the first direction when the scanner is disposed in the processing position to form a processing pattern further comprises stopping the stage when the scanner is located in the processing position.

14. The method of claim 13, wherein the processing position includes a first processing position and a second processing position spaced apart from the first processing position in the first direction, and
the irradiating a laser beam to a processing position while moving both a scanner and the stage in the first direction when the scanner is disposed in the processing position to form a processing pattern further comprises moving the scanner in the first direction when the scanner is located between the first processing position and the second processing position.

15. The method of claim 14, wherein a moving speed of the scanner is equal to a moving speed of the stage.

16. A method for manufacturing a display device, comprising:
moving a stage in a first direction; and
irradiating a laser beam to a processing position while moving both a scanner and the stage in the first direction when the scanner is disposed in the processing position to form a processing pattern,
wherein the irradiating a laser beam to a processing position while moving both a scanner and the stage in the first direction when the scanner is disposed in the processing position to form a processing pattern comprises:
outputting, by a laser module irradiating the laser beam, a first pulse signal including a plurality of first pulses;
when a moving distance of the scanner is equal to an irradiation interval of the laser beam in the processing position, generating a second pulse signal including a second pulse synchronized with one of the plurality of first pulses; and
generating a third pulse signal including a plurality of third pulses by using the second pulse signal and providing the third pulse signal to the laser module.

17. The method of claim 16, wherein the laser module outputs the laser beam in synchronization with the plurality of third pulses of the third pulse signal.

18. The method of claim 16, wherein one of the plurality of third pulses is synchronized with the second pulse of the second pulse signal.

19. The method of claim 16, wherein the second pulse signal includes a second pulse synchronized to another one of the plurality of first pulses, and
an interval between the second pulses is equal to an irradiation repetition period of a group of the laser beams.

20. The method of claim 16, wherein an interval between the plurality of third pulses is equal to an irradiation interval of the laser beam.
